(19) United States
(12) Patent Application Publication
(10) Pub. No.: US 2009/0166005 A1
(43) Pub. Date: Jul. 2, 2009

(54) VAPOR CHAMBER

(75) Inventors: CHENG-TIEN LAI, Tu-Cheng (TW); ZHI-YONG ZHOU, Shenzhen (CN); QIAO-LI DING, Shenzhen (CN)

Correspondence Address: PCE INDUSTRY, INC.;ATT. Steven Reiss, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/967,069

(22) Filed: Dec. 29, 2007

(51) Int. Cl. F28D 15/04; H01L 23/427

(52) U.S. Cl. 165/104.26

(57) ABSTRACT

A vapor chamber includes a base (100) and a cover (200). The cover is mounted on the base with a hermetically sealed cavity (102) defined between the base and the cover. A working fluid is contained in the cavity. A first wick structure (220) is spread on an inner surface (201) of the cover. A second wick structure (221) is disposed in the cavity. A third wick structure (110) is spread on an inner surface (101) of the base, and the second wick structure extends between the first wick structure and the third wick structure. A first vapor space (300) is defined in the cavity and surrounds the second wick structure. A second vapor space (400) is defined in the second wick structure and communicated with the first vapor space.

### BACKGROUND OF THE INVENTION

1. Field of the Invention

The present invention relates to a vapor chamber, and particularly to a vapor chamber having a good heat transfer capability with a small thickness.

2. Description of Related Art

As computer technology continues to advance, electronic components such as central processing units (CPUs) of computers are being made to provide faster operational speeds and greater functional capabilities. When a CPU operates at a high speed in a computer enclosure, its temperature usually increases enormously. It is therefore desirable to dissipate the generated heat of the CPU quickly before damage is caused.

A vapor chamber is usually used to help heat dissipation for a heat-generating component. The vapor chamber generally includes a base and a cover mounted on the base with a sealed chamber formed between the base and the cover. The base has a wick structure spread on the whole inner surface thereof, and the cover has a wick structure spread on the whole inner surface thereof. A hollow vapor flowing passage is defined between the wick structures. During operation, the base absorbs heat from the heat-generating component, and the working fluid is heated into vapor. The vapor flows towards the cover along the vapor flowing passage and dissipates the heat thereto, then condenses into fluid and returns back to the base driven by the wick structures to continue the cycle.

However, the trends for electronics products are toward smaller size, lighter weights, higher speeds, thus the thickness of the vapor chamber has to be reduced to suit for the trends. This leads to a reduction of a thickness of the vapor flowing passage and a large resistance to the vapor flowing in the vapor flowing passage. This will adversely affect the heat transfer capability of the vapor chamber.

What is needed, therefore, is a vapor chamber which has a good heat transfer capability with a small thickness.

### SUMMARY OF THE INVENTION

In accordance with an embodiment of the present invention, a vapor chamber comprises a base and a cover. The cover is mounted on the base with a hermetically sealed cavity formed between the base and the cover. A working fluid is contained in the cavity. A first wick structure is spread on an inner surface of the cover. A second wick structure is disposed in the cavity. A third wick structure is spread on an inner surface of the base, and the second wick structure extends between the first wick structure and the third wick structure. A first vapor space is defined in the cavity and surrounds the second wick structure. A second vapor space is defined in the second wick structure and communicated with the first vapor space.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an assembled view of a vapor chamber in accordance with a preferred embodiment of the present invention;

FIG. 2 is a cross-sectional view of FIG. 1;

FIG. 3 is an enlarged view of a circle portion 111 of FIG. 2;

FIG. 4 is an exploded view of FIG. 1, viewed from an upside down aspect; and

FIG. 5 is an isometric view of a first wick structure and a second wick structure of a vapor chamber in accordance with another preferred embodiment of the present invention.

### DETAILED DESCRIPTION OF THE INVENTION

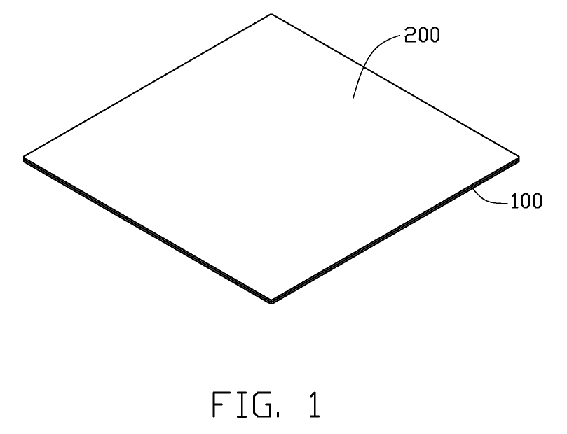

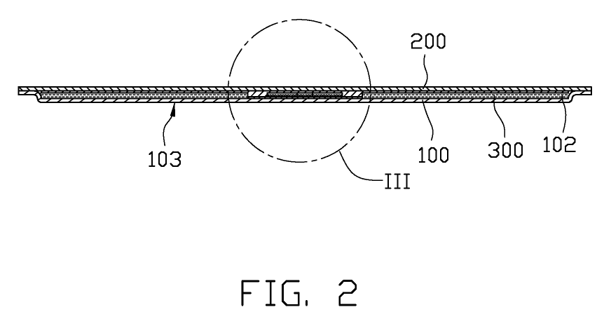

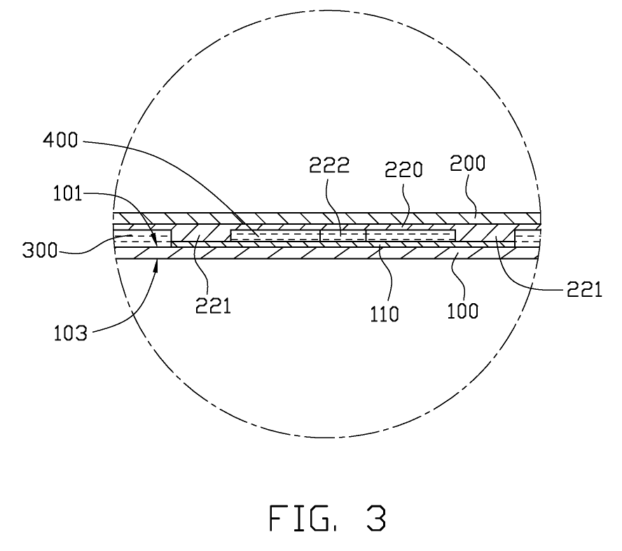

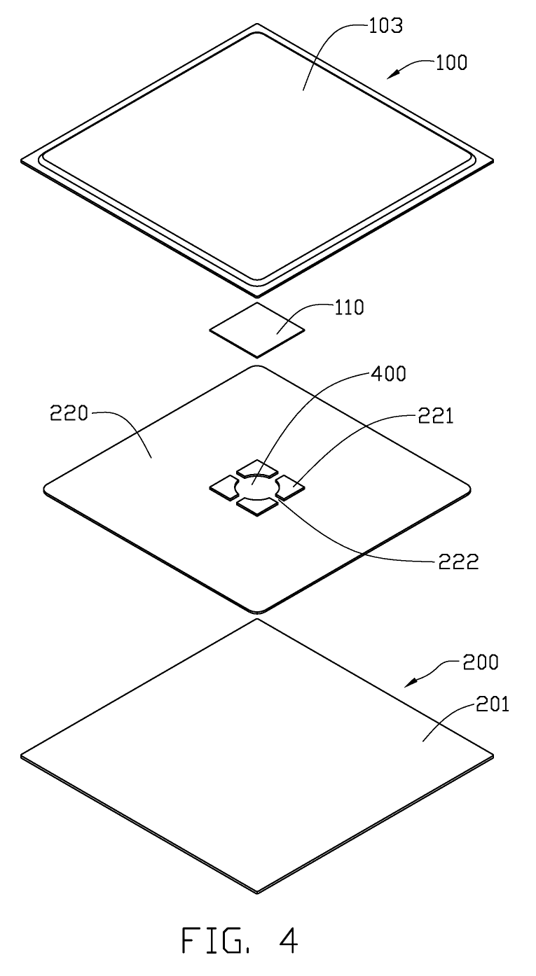

Referring to FIGS. 1-4, a vapor chamber according to a preferred embodiment of the invention is illustrated. The vapor chamber includes a base 100 with a cavity 102 and a cover 200 mounted on the base 100 to thereby hermetically seal the cavity 102 of the base 100. A predetermined quantity of working fluid such as water is contained in the cavity 102 for transferring heat from the base 100 to the cover 200 via phase transition. The cavity 102 is evacuated for easily evaporating the working fluid.

The vapor chamber further comprises a first wick structure 220 formed on an inner surface 201 of the cover 200, a second wick structure 221, a third wick structure 110 formed on an inner surface 101 of the base 100. The second wick structure 221 is extended from the first wick structure 220 to the third wick structure 110 with a first vapor space 300 defined in the cavity 102. The first vapor space 300 surrounds the second wick structure 221 and has a ring shaped profile. A second vapor space 400 is defined in the second wick structure 221 and communicates with the first vapor space 300.

The base 100 and the cover 200 are made of copper, aluminum or other material having a good heat conductivity. The base 100 has a bottom surface 103 in thermal contact with a heat-generating component (not shown), and absorbs heat produced by the heat-generating component. In generally, the heat-generating component is attached to a center portion of the bottom surface 103 of the base 100.

The third wick structure 110 is locally formed on the inner surface 101 of the base 100 at a position corresponding to the heat-generating component. The third wick structure 110 serves to keep the center portion of the inner surface 101 of the base 100 wet, so as to prevent the vapor chamber from drying out. The third wick structure 110 has a rectangular profile, and has a size identical to that of the heat-generating component but smaller than that of the cavity 102 of base 100. In other words, the first vapor space 300 is defined by an outer circumferential portion of the cavity 102 and surrounds the third wick structure 110. This helps to reduce the thickness of the vapor chamber without increase of the resistance to the vapor.

The first wick structure 220 wholly is spread on the inner surface 201 of the cover 200 and faces the third wick structure 110. The second wick structure 221 has a size mating with the size of the third wick structure 110. The second wick structure 221 is extended from a center portion of the first wick structure 220 to the third wick structure 110, until the second wick structure 221 abutting against a circumferential edge of the third wick structure 110. As a result, the first wick structure 220 and the third wick structure 110 are connected together via the second wick structure 221. The first wick structure 220, the second wick structure 221, and the third wick structure 110 can be selected from one of metal screen, sintered powder, nanotube array, bundle of fibers and so on. Furthermore, the first wick structure 220 and the third wick structure 110 can be made of grooves.

The second vapor space 400 is a void defined in an inner portion of the second wick structure 221, and faces the top surface of the third wick structure 110. A plurality of channels 222 is defined in the second wick structure 221 and extends in a radial direction. The channels 222 are evenly spaced from each other along the second wick structure 221. The first vapor space 300 and the second vapor passage 400 are communicated with each other via the channels 222. Therefore, the vapor of the working fluid can freely flow between the first vapor space 300 and the second vapor space 400 through the channels 222.

During operation of the vapor chamber, the heat-generating component is attached to the base 100 under the third wick structure 110, and the base 100 absorbs heat produced by the heat-generating component, and working fluid saturated in the third wick structure 110 is heated into vapor. The vapor escapes from the third wick structure 110, flows quickly into the second vapor space 400 due to smaller pressure, and is quickly diffused into the whole first vapor space 300 through the channels 222. When the vapor contacts the first wick structure 220 on the cover 200, it gives out heat and condenses into fluid. The condensed working fluid is then pumped back to the third wick structure 110 through the second wick structure 221.

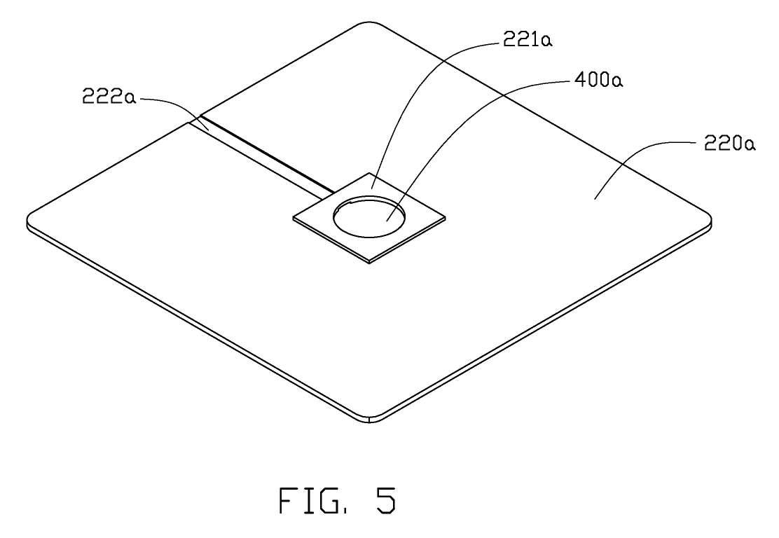

Referring to FIG. 5, a first wick structure 220a and a second wick structure 221a of a vapor chamber according to another preferred embodiment of the invention is illustrated. The main difference between the first wick structure 220a, the second wick structure 221a of this embodiment and that of the previous embodiment is that: the second wick structure 221a has a ring shaped profile, and a channel 222a is defined in the second wick structure 221a and extends into the first wick structure 220a. A second vapor space 400a is defined in the second wick structure 221a and communicated with the first vapor space 300 through the channel 222a.

As mentioned above, the third wick structure 110 is locally formed on the inner surface 101 of the base 100, particularly on the center portion of the inner surface 101 of the base 100 corresponding to the heat-generating component. By virtue of such design, the third wick structure 110 occupies small spaces and thus the first vapor space 300 has a large size when the vapor chamber is designed to have a small thickness.

Furthermore, the presence of the second vapor space 400, 400a above the third wick structure 110, reduces the pressure around the third wick structure 110, which is caused by continuous evaporation of the working fluid and which prevents the vapor from escaping from the third wick structure 110. Therefore, the working fluid absorbs the heat produced by the heat-generating component, and is easily evaporated so as to transfer the heat from the base 100 to the cover 200.

Additionally, the condensed working fluid can flow quickly back to the center portion of the base 100 driven by the gravity and the hydraulic difference between the first wick structure 220 and the third wick structure 110.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A vapor chamber comprising:
a base;
a cover mounted on the base with a hermetically sealed cavity formed between the base and the cover;
a working fluid contained in the cavity;
a first wick structure spread on an inner surface of the cover;
a second wick structure disposed in the cavity;
a third wick structure spread on an inner surface of the base, the second wick structure extending between the first wick structure and the third wick structure;
a first vapor space defined in the cavity and surrounding the second wick structure; and
a second vapor space defined in the second wick structure and communicated with the first vapor space.

2. The vapor chamber as described in claim 1, wherein the second wick structure extends from the first wick structure towards the third wick structure and abuts against the third wick structure.

3. The vapor chamber as described in claim 1, wherein at least a channel is defined in the second wick structure, and the second vapor space communicates with the first vapor space through the at least a channel.

4. The vapor chamber as described in claim 3, wherein the second wick structure has a plurality of channels defined therein, the channels being evenly spaced from each other along the second wick structure.

5. The vapor chamber as described in claim 1, wherein the second wick structure has a ring shaped profile.

6. The vapor chamber as described in claim 5, wherein at least a channel is defined in the second wick structure, and the second vapor space communicates with the first vapor space through the at least a channel, the least a channel extends into the first wick structure.

7. The vapor chamber as described in claim 1, wherein the second wick structure and the third wick structure are disposed in a center portion of the cavity.

8. The vapor chamber as described in claim 7, wherein the first vapor space has a ring shape.

9. A vapor chamber comprising:
a base;
a cover mounted on the base with a hermetically sealed cavity formed between the base and the cover;
a working fluid contained in the cavity;
a first wick structure spread on a whole inner surface of the cover;
a second wick structure disposed in the cavity and connecting the first wick structure to the base;
a first vapor space defined in the cavity and surrounding the second wick structure; and
a second vapor space defined in the second wick structure and communicated with the first vapor space.

10. The vapor chamber as described in claim 9, wherein a third wick structure is locally formed on a center portion of an inner surface of the base, and the second wick structure is extended between the first wick structure and the third wick structure.

11. The vapor chamber as described in claim 10, wherein the second wick structure has a channel defined therein, and the first vapor space and the second vapor space are communicated with each other through the channel.

12. The vapor chamber as described in claim 10, wherein the second wick structure and the third wick structure are positioned in a center portion of the cavity.

13. The vapor chamber as described in claim 9, wherein the first vapor space surrounds the second vapor space.
